(19) United States
(12) Patent Application Publication
(10) Pub. No.: US 2019/0022609 A1
(43) Pub. Date: Jan. 24, 2019

(54) MIXER STRUCTURE, FLUID PASSAGE DEVICE, AND PROCESSING DEVICE

(71) Applicant: Kabushiki Kaisha Toshiba, Minato-ku (JP)

(72) Inventors: Takahiro TERADA, Yokohama (JP); Masayuki TANAKA, Yokohama (JP); Shiguma KATO, Yokohama (JP); Shinji NAKATA, Yokohama (JP); Morihiro MACHIDA, Chuo (JP)

(73) Assignee: Kabushiki Kaisha Toshiba, Minato-ku (JP)

(21) Appl. No.: 15/757,657

(22) PCT Filed: Nov. 25, 2016
(86) PCT No.: PCT/JP2016/085016

§ 371 Date: Mar. 6, 2018

(30) Foreign Application Priority Data
Mar. 15, 2016 (JP) 2016-051176

(51) Int. Cl. B01F 5/06; B01F 3/02; B01F 15/00; C23C 16/455

(52) U.S. Cl. CPC B01F 5/0645; B01F 3/02; B01F 2005/0017; C23C 16/45512; B01F 15/00915

(57) ABSTRACT

A mixer structure includes a helical fluid passage includes a first partition and a second partition. The first partition extends intersecting with a cross-sectional center line of the passage, and divides the helical passage into first sub-passages in parallel. The second partition is disposed downstream of the first partition, extends intersecting with the cross-sectional center line, and divides the helical passage into second sub-passages in parallel. A rear or downstream end of the first partition and a front or upstream end of the second partition intersect with each other or are at skew position.

### FIELD

Embodiments relate to a mixer structure, a fluid passage device, and a processing device.

### BACKGROUND

Conventionally, a processing device that mixed gas execute predetermined processing using a process has been known.

### CITATION LIST

### Patent Literature

Patent Literature 1: Japanese Patent Application Laid-open No. 2012-182166

### SUMMARY OF THE INVENTION

### Problem to be Solved by the Invention

For example, it is useful to provide a mixer structure that can more uniformly or more efficiently mix fluid such as gas.

### Means for Solving Problem

According to one embodiment, a mixer structure provided with a helical passage for fluid, includes a first partition and a second partition. A first partition extends intersecting with a cross-sectional center line of the helical passage, and divides the helical passage into a plurality of first sub-passages in parallel. A second partition that is disposed downstream of the first partition, extends intersecting with the cross-sectional center line, and divides the helical passage into a plurality of second sub-passages in parallel. A rear end of the first partition and a front end of the second partition intersect each other or are at skew position relative to each other. The rear end is a downstream end, and the front end is an upstream end.

### BRIEF DESCRIPTION OF DRAWINGS

FIG. 1 is a schematic exemplary sectional view of a processing device of an embodiment.

FIG. 2 is a schematic exemplary sectional view of a fluid passage device of a first embodiment.

FIG. 3 is a cross-sectional view of FIG. 2 taken along a line III-III.

FIG. 4 is a cross-sectional view of FIG. 2 taken along a line IV-IV.

FIG. 5 is a schematic exemplary diagram illustrating cross sections of one of passage sections in the fluid passage device of the first embodiment, at positions S1 to S8 illustrated in FIG. 4.

FIG. 6 is a schematic exemplary diagram illustrating cross sections of a passage section adjacent to the downstream side of the section illustrated in FIG. 5, in the fluid passage device of the first embodiment, at the positions S1 to S8 illustrated in FIG. 4.

FIG. 7 is a schematic exemplary sectional view illustrating an arrangement of a front end of a second partition and a rear end of a first partition in the passage of the fluid passage device of the first embodiment.

FIG. 8 is a schematic exemplary sectional view of a part of a fluid passage device according to a modification.

FIG. 9 is a schematic exemplary sectional view of a fluid passage device of a second embodiment.

### DETAILED DESCRIPTION

Hereinafter, exemplary embodiments of a mixer structure, a fluid passage device, and a processing device will be disclosed. Configurations and control (technical features) in the embodiments to be described below, and functions and results (effects) brought by the configurations and control are merely examples. In the drawings, an X direction, a Y direction, and a Z direction are defined for the sake of simple explanation. The X direction, the Y direction, and the Z direction are perpendicular to one another.

The following embodiments and modification include same or like elements. In the following, same or like reference numerals denote the same or like elements, and a repetitive description thereof will be omitted.

### First Embodiment

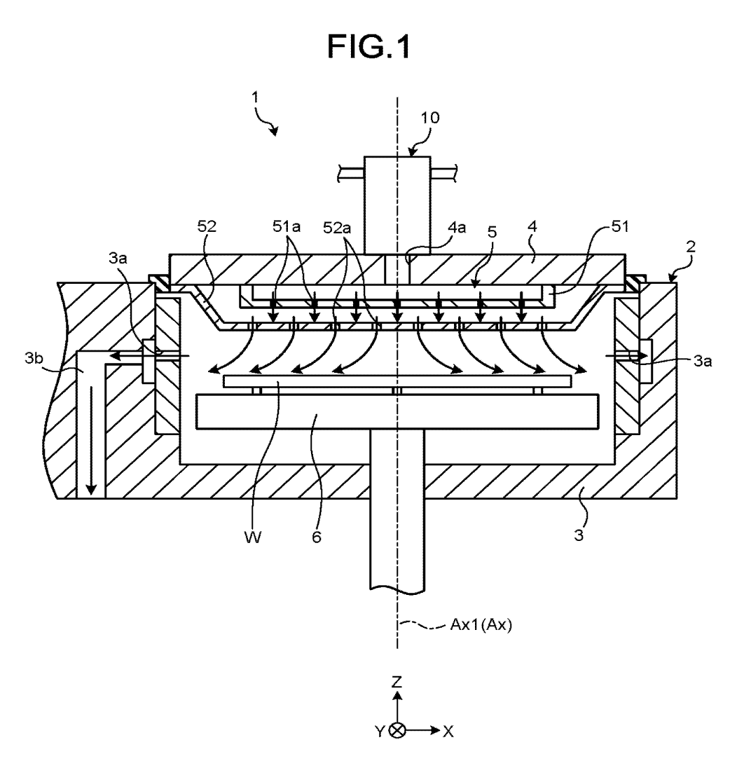

FIG. 1 is a cross section of a semiconductor processing device 1. The semiconductor processing device 1 includes a chamber 2 (treatment container) of a substantially cylindrical shape with a base 3 and a lid 4 in which a wafer W is subjected to a predetermined process. The semiconductor processing device 1 is, for example, a chemical vapor deposition (CVD) device, and forms a silicone oxide film on the wafer W as an insulating film such as an interlayer insulating film. The base 3 and the lid 4 may also be referred to as walls. The semiconductor processing device 1 is an example of a processing device. The chamber 2 is an example of a processing unit. The wafer W is an example of an intended object.

A shower mechanism 5 for supplying gas onto the wafer W is provided on the lid 4. The shower mechanism 5 includes a plurality of plates 51 and 52 arranged with intervals. The plates 51 and 52 are provided with through holes 51a and 52a through which gas passes. Specifications of the through holes 51a and 52a including position, number, and size are set to reduce variation in the gas supply amount depending on a position on the wafer W as small as possible.

The wafer W is supported by a disc-like stage 6 in the chamber 2. The stage 6 can rotatably support the wafer W around a central axis Ax in a thickness direction of the wafer W. The stage 6 may also include a heater, which is not illustrated, for heating the wafer W.

The lid 4 has an inlet 4a. Gas is introduced into the shower mechanism 5 and the chamber 2 via the inlet 4a. The base 3 has an outlet 3a and an exhaust passage 3b. The gas is discharged from the chamber 2 via the outlet 3a and the exhaust passage 3b.

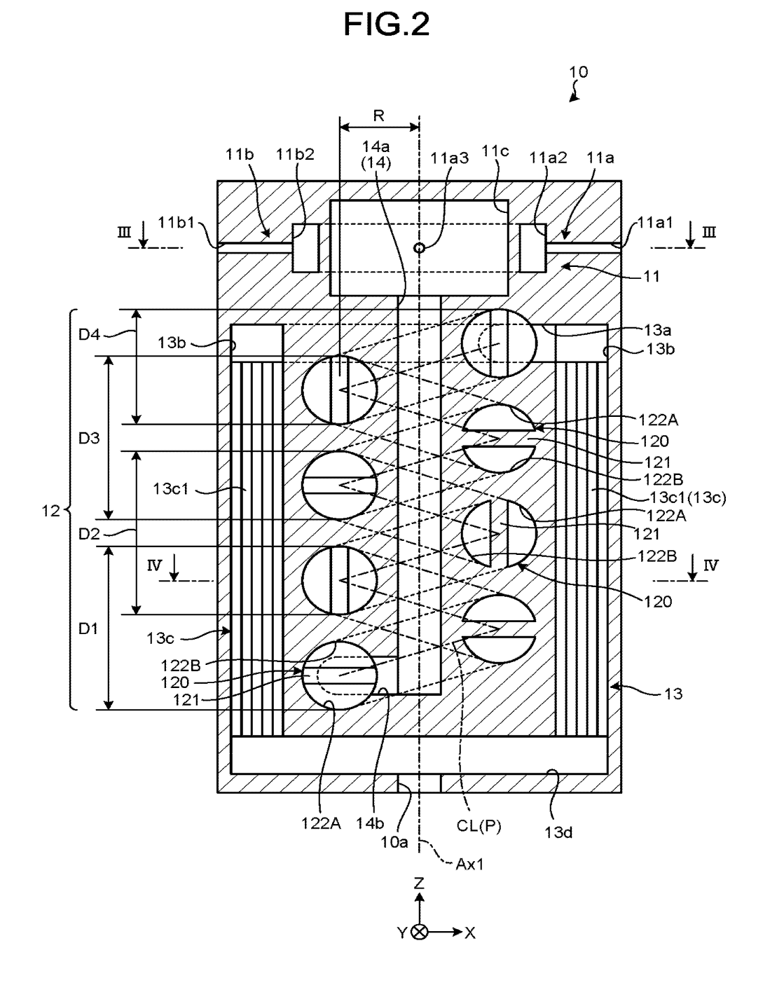

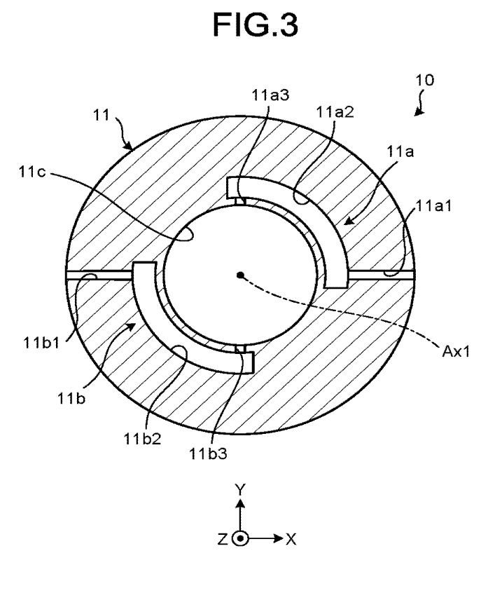

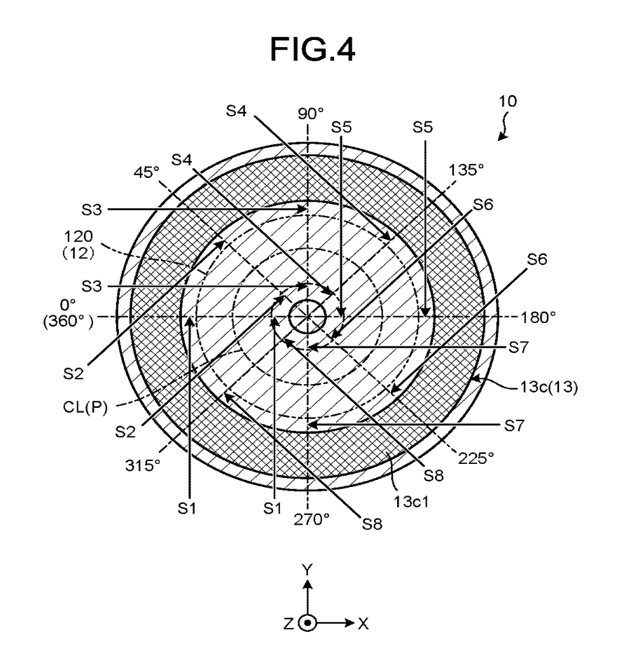

FIG. 2 is a sectional view of a mixer 10. FIG. 3 is a cross-sectional view of FIG. 2 taken along a line III-III. FIG. 4 is a cross-sectional view of FIG. 2 taken along a line IV-IV. As illustrated in FIG. 1, in the present embodiment, the mixer 10 is provided upstream of the inlet 4a for mixing gases. More specifically, for example, the mixer 10 with a cylindrical appearance is disposed on the top center of the lid 4. The mixer 10 is an example of a mixer structure. The mixer 10 may be integrally formed with the lid 4, or may be separately formed from the lid 4 and attached to the lid 4. The center line of the cylindrical mixer 10 may be referred to as a central axis Ax1. The central axis Ax1 is the same as the central axis Ax of the stage 6. In the following explanation, axial, radial, and circumferential directions are defined on the basis of the central axis Ax1. The mixer 10 is an example of a fluid passage device. For example, the mixer 10 may be created by an additive manufacturing device.

The mixer 10 includes a premixer 11, a helical static mixer 12, and a flow straightening unit 13. The premixer 11 is an example of a second mixer. The helical static mixer 12 is an example of a first mixer.

The premixer 11 causes the gases to collide with one another for accelerating the mixing. As illustrated in FIG. 3, the premixer 11 includes a first passage 11a, a second passage 11b, and a mixing chamber 11c. The first passage 11a and the second passage 11b are for introducing different gases into the mixing chamber 11c, respectively. The gas that has passed through the first passage 11a and the gas that has passed through the second passage 11b collide with each other in the mixing chamber 11c.

The mixing chamber 11c is positioned downstream in the premixer 11. The mixing chamber 11c has a cylindrical shape around the central axis Ax1 and is positioned in the center of the premixer 11.

The first passage 11a is positioned upstream of the mixing chamber 11c. The first passage 11a includes three serial sections of an introductory section 11a1, a circulation section 11a2, and an ejection section 11a3. The introductory section 11a1 extends radially inward from an introductory opening in the outer peripheral surface of the mixer 10. The circulation section 11a2 lies downstream of the introductory section 11a1. The circulation section 11a2 extends circumferentially from a radially inner end of the introductory section 11a1, in other words, from the downstream end of the introductory section 11a1. The ejection section 11a3 lies downstream of the circulation section 11a2. The ejection section 11a3 extends radially inward to an ejection opening of the mixing chamber 11c from an opposite end of the circulation section 11a2 to the introductory section 11a1, in other words, from the downstream end of the circulation section 11a2. In the first passage 11a having such a configuration, the gas is introduced into the mixing chamber 11c through the introductory section 11a1, the circulation section 11a2, and the ejection section 11a3. In this example, as apparent from FIG. 2, the area of the passage cross-section of the ejection section 11a3, for example, the cross-section perpendicular to the direction of flow, is smaller than that of the passage cross-section of the circulation section 11a2. Consequently, the gas is ejected from the ejection section 11a3 into the mixing chamber 11c at a higher speed than that in the circulation section 11a2. The ejection section 11a3 may also be referred to as a nozzle, a throttle, or an orifice.

The second passage 11b is positioned upstream of the mixing chamber 11c. The second passage 11b includes three serial sections of an introductory section 11b1, a circulation section 11b2, and an ejection section 11b3. The introductory section 11b1 extends radially inward from an introductory opening in the outer peripheral surface of the mixer 10. The circulation section 11b2 lies downstream of the introductory section 11b1. The circulation section 11b2 extends circumferentially from a radially inner end of the introductory section 11b1, in other words, from the downstream end of the introductory section 11b1. The ejection section 11b3 lies downstream of the circulation section 11b2. The ejection section 11b3 extends radially inward to an ejection opening of the mixing chamber 11c from an opposite end of the circulation section 11b2 to the introductory section 11b1, in other words, from the downstream end of the circulation section 11b2. In the second passage 11b having such a configuration, gas is introduced into the mixing chamber 11c through the introductory section 11b1, the circulation section 11b2, and the ejection section 11b3. As apparent from FIG. 2, the area of the passage cross-section of the ejection section 11b3, for example, the cross-section perpendicular to the direction of flow, is smaller than that of the passage cross-section of the circulation section 11b2. Consequently, the gas is ejected from the ejection section 11b3 into the mixing chamber 11c at a higher speed than that in the circulation section 11b2. The ejection section 11b3 may also be referred to as a nozzle, a throttle, or an orifice. As apparent from FIG. 2, the second passage 11b is symmetric to the first passage 11a with respect to the central axis Ax1. Moreover, the ejection section 11a3 of the first passage 11a and the ejection section 11b3 of the second passage 11b extend radially, facing each other across the central axis Ax1. Thus, in the mixing chamber 11c, jet flows of gases from the ejection section 11a3 and from the ejection section 11b3 collide against each other from opposite directions. Collision of the jet flows of gases as above accelerates the mixing of gases. Moreover, collision of the jet flows of gases from the opposite directions further accelerates the mixing of gases.

The mixing chamber 11c of the premixer 11 and a passage 120 of the helical static mixer 12 are connected via a connecting passage 14. The connecting passage 14 includes a vertical hole 14a and a horizontal hole 14b. The vertical hole 14a has a cylindrical shape and extends axially on the central axis Ax1. The horizontal hole 14b extends radially from an opposite end of the vertical hole 14a to the mixing chamber 11c. The vertical hole 14a is an example of an introductory passage.

As illustrated in FIG. 2, the helical static mixer 12 includes the passage 120 having a helical (spiral) shape, extending along the central axis Ax1 while twisting around the central axis Ax1. The passage 120 extends between the upstream end connected to the horizontal hole 14b of the connecting passage 14 and the downstream end connected to a horizontal hole 13a of the flow straightening unit 13. For example, the helical passage 120 can be defined as follows. For example, positional coordinates (pₓ, p_{y}, and p_{z}) of a point P (cross-sectional center) of a cross-sectional center line CL of the passage 120 can be expressed by the following formulae (1) to (3):

pₓ=R·cos θ (1)

p_{y}=R·sin θ (2)

p_{z}=h·θ (3)

where pₓ is the positional coordinate of the point P in the X direction, p_{y} is the positional coordinate of the point P in the Y direction, p_{z} is the coordinate of the point P in the Z direction, θ is a parameter (angle around the central axis Ax1), R is the radius of a helix, and h is a coefficient proportional to pitch (interval in the Z direction) of the helix.

The cross-section of the passage may be along a plane including the central axis Ax1, or may be perpendicular to the tangential direction of the point P of the cross-sectional center line CL. Unit vectors (tₓ, t_{y}, and t_{z}) of the point P of the cross-sectional center line CL in the tangential direction can be expressed by the following formulae (4) to (6):

tₓ=−sin α·sin θ (4)

t_{y}=sin α·cos θ (5)

t_{z}=cos α (6)

where cos α=h and sin α=R. In this case, the passage cross-section at the point P is a face that passes the point P, in which the tangential direction of the cross-sectional center line CL at the point P matches normal direction. For example, the direction of flow in the passage 120 may be defined as the tangential direction at the point P of the helical cross-sectional center line CL.

The center of each of the passage cross-sections, that is, the point P, is set to the geometric centroid of an opening of the passage 120 in each of the passage cross-sections.

The passage 120 includes multiple sections in series. In the example in FIG. 2, the passage includes four sections D1 to D4. The lengths of the sections may be the same or may be different.

Each of the sections D1 to D4 includes a partition 121. The partition 121 divides the passage 120 into sub-passages 122A and 122B in parallel. In the example in FIG. 2, the partition 121 divides the passage 120 into two parallel sub-passages 122A and 122B. In each of the passage cross-sections, the cross-sectional shape of the sub-passages 122A and 122B is a D-shape. The two sub-passages 122A and 122B are disposed so that the straight lines of the D-shapes are aligned in parallel with a gap, and the curved lines of the D-shapes are placed on a single circumference, that is, linear symmetric or point symmetric to each other. Moreover, in each of the passage cross-sections, the partition 121 has a belt-like shape that passes the cross-sectional center (point P) and linearly extends in one direction at a constant width. In other words, the partition 121 extends between the straight lines of the two D-shapes in each of the passage cross-sections, and divides the passage 120 to have the cross-sectional areas of the two sub-passages 122A and 122B coincide with each other. That is, the plate-like partition 121 works to segment the helically-extending passage 120 with a circular cross-section into the parallel sub-passages 122A and 122B having substantially the same volume. The cross-sectional areas of the sub-passages 122A and 122B are constant in the sections D1 and D4, but may differ. The helical static mixer 12 is an example of a mixer structure.

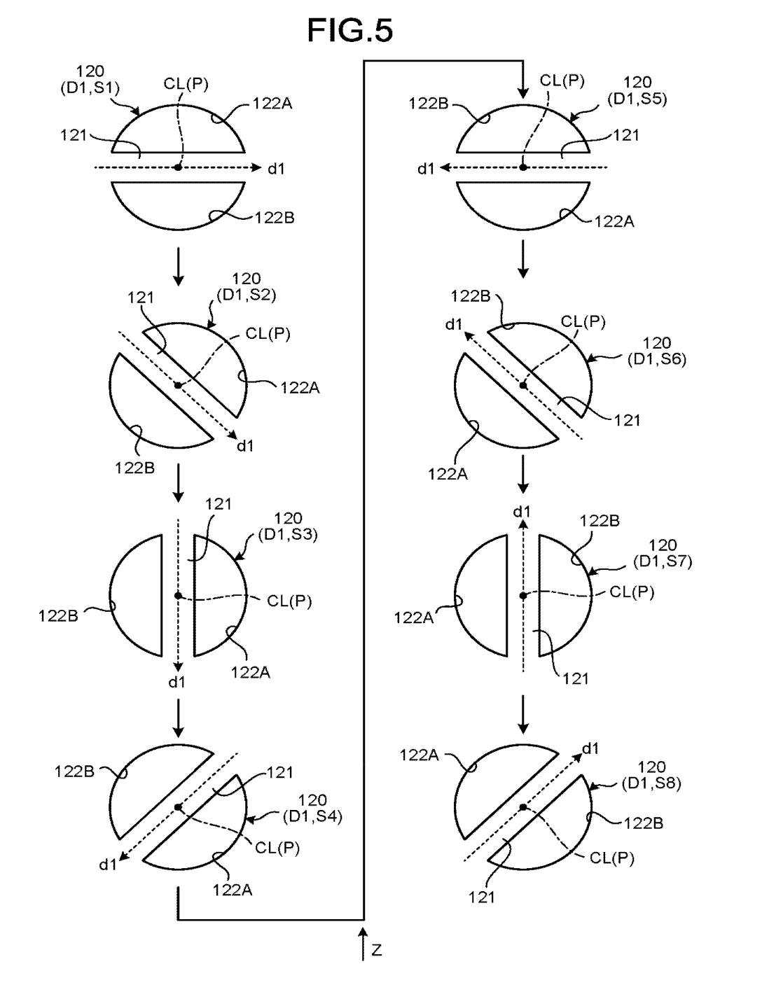

FIG. 5 is a diagram illustrating passage cross-sections of the section D1 of the passage 120 at positions S1 to S8 (cross-sectional lines and angles) illustrated in FIG. 4. The position S1 is most upstream, and the position S8 is most downstream. The positions S1 to S8 are such that the larger the assigned numeral is, the more downstream the position is. In the example in FIG. 5, in the circumferential and downstream directions of the passage cross-section, the partition 121, which extends in a direction d1 intersecting with the cross-sectional center line CL, is gradually twisted downstream clockwise. In the section D1, the partition 121 rotates 360 degrees around the cross-sectional center line CL while the passage 120 helically rotates 360 degrees around the central axis. With such a configuration, the flow of gas grows into a helical vortex along the partition 121 in the sub-passages 122A and 122B. Thereby, the mixing of gases is accelerated. The direction d1 is an example of a first direction.

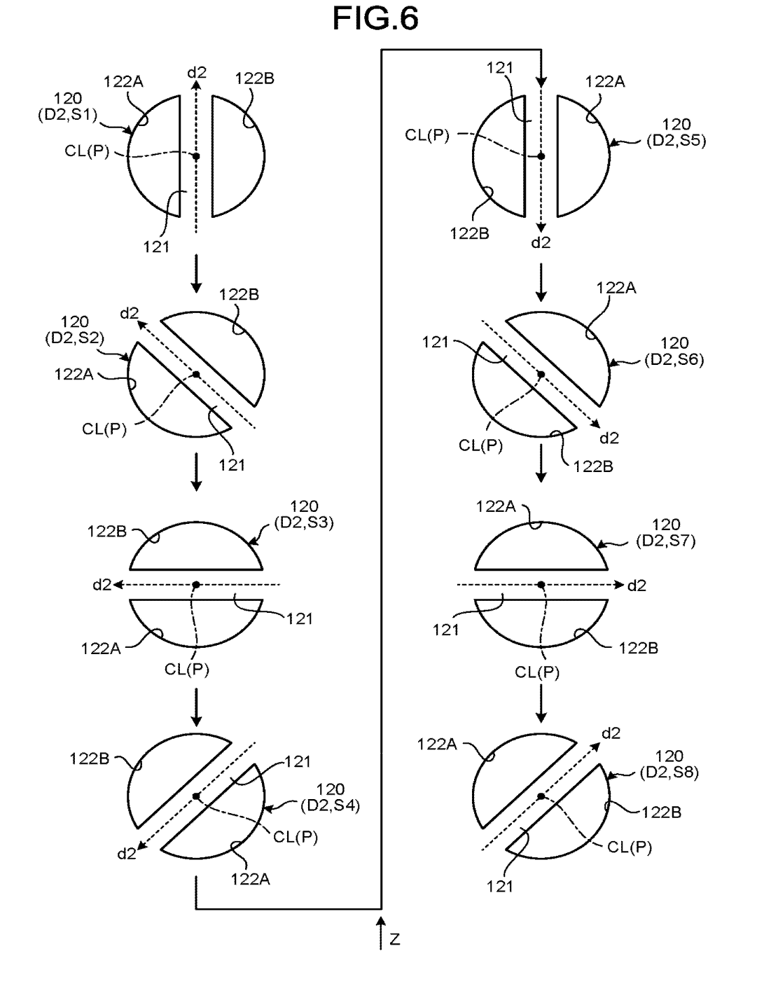

FIG. 6 is a diagram illustrating passage cross-sections of the section D2 adjacent to the downstream side of the section D1 at the positions S1 to S8 (cross-sectional lines and angles) illustrated in FIG. 4. In the example in FIG. 6, in the circumferential and downstream directions of the passage cross-section, the partition 121, which extends in a direction d2 intersecting with the cross-sectional center line CL, is gradually twisted downstream counterclockwise. In the section D2, the partition 121 rotates 360 degrees around the cross-sectional center line CL while the passage 120 helically rotates 360 degrees around the central axis. With such a configuration, the flow of gas grows into a helical vortex along the partition 121 in the sub-passages 122A and 122B. Thereby, the mixing of gases is accelerated. The direction d2 is an example of a second direction.

As apparent from comparison between FIGS. 5 and 6, the partition 121 is twisted downstream in different directions in the two adjacent sections D1 and D2 in the flow direction. This facilitates occurrence of a turbulent flow in the two adjacent sections D1 and D2 in the flowing direction from when the partition 121 is twisted in the same direction, leading to further accelerating the mixing of gases. The partition 121 in the upstream section D1 between the two sections D1 and D2 is an example of a first partition. The sub-passages 122A and 122B in the upstream section D1 are an example of a first sub-passage. The partition 121 in the downstream section D2 between the two serially adjacent sections D1 and D2 in the flow direction is an example of a second partition. The sub-passages 122A and 122B in the downstream section D2 are an example of a second sub-passage.

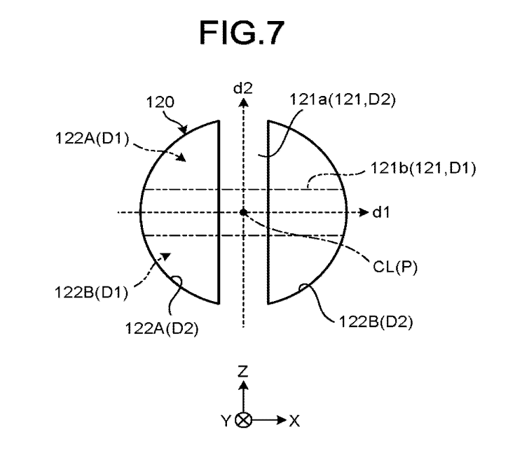

FIG. 7 is an diagram illustrating a front end 121a of the partition 121 in the section D2 and a rear end 121b of the partition 121 in the section D1 adjacent to the upstream side of the section D2. The front end 121a is the upstream end of the partition 121 in the section D2, and linearly extends in the Z direction (direction d2) or the width direction of the passage 120. On the other hand, the rear end 121b is the downstream end of the partition 121 in the section D1, and linearly extends in the X direction (direction d1) or the width direction of the passage. As apparent from FIG. 7, the rear end 121b of the partition 121 in the section D1 and the front end 121a of the partition 121 in the section D2 adjacent to the downstream side of the section D1 intersect with each other. This facilitates occurrence of a turbulent flow in the two sections D1 and D2 from when the rear end 121b of the partition 121 in the upstream section D1 and the front end 121a of the partition 121 in the downstream section D2 are in parallel with each other, leading to further accelerating the mixing of gases. Moreover, in the example in FIG. 7, in the downstream side of the passage cross-section, the rear end 121b of the section D1 and the front end 121a of the section D2 are perpendicular to each other. Thus, the gas flows substantially in half into the two sub-passages 122A and 122B in the downstream section D2 from the two sub-passages 122A and 122B in the upstream section D1. When the number of combinations of the sections having such front ends 121a and rear ends 121b is n, the flow is divided 2ⁿ times and mixed, which results in reducing variation in gas components depending on the position of the cross-section of the passage. In this example, in the two serially adjacent sections D1 and D2, the rear end 121b of the partition 121 in the upstream section D1 and the front end 121a of the partition 121 in the downstream section D2 contact with each other and intersect with each other. However, they may be separated from each other with the respective central parts facing each other with a gap. The rear end 121b of the partition 121 in the upstream section and the front end 121a of the partition 121 in the downstream section may be at skew position relative to each other, if they are separated.

The passage 120 further includes the section D3 downstream of the section D2 and the section D4 downstream of the section D3. The section D3 has the same shape as that of the section D1, and the section D4 has the same shape as that of the section D2. However, the length of the section D4 is a half of that of the section D2, in other words, a length equal to 180 degrees around the central axis Ax1.

As illustrated in FIG. 2, the flow straightening unit 13 includes the horizontal hole 13a, a third passage 13b, a flow straightening passage 13c, and a fourth passage 13d. The horizontal hole 13a connects the downstream end of the section D4 in the passage 120 and the third passage 13b together. The horizontal hole 13a may be referred to as an introducer of the flow straightening unit 13. The third passage 13b has an annular shape. The flow straightening passage 13c continues to an axial end of the third passage 13b (downward in FIG. 2), and has a cylindrical shape, surrounding the helical static mixer 12. The flow straightening passage 13c includes parallel holes 13c1, extending along the axis (central axis Ax1) of the cylinder. As illustrated in FIG. 4, for example, the cross-section of the holes 13c1 is densely arranged quadrangles in mesh form. For example, the cross-sectional shape of the holes 13c1 is not limited to quadrangular, and may also be circular, oval, or hexagonal, for instance. With the holes 13c1 having a hexagonal cross-section, the flow straightening passage 13c has a honeycomb structure. As illustrated in FIG. 2, the fourth passage 13d is flat and cylindrical and is connected to the holes 13c1. The gas that has passed through the fourth passage 13d is introduced to the inlet 4a of the lid 4 through an outlet 10a of the mixer 10. With such a configuration, the gas, while being straightened in the flow straightening passage 13c of the flow straightening unit 13, is introduced into the chamber 2.

As described above, in the present embodiment, the rear end 121b of the partition 121 (first partition) in the section D1 and the front end 121a of the partition 121 (second partition) in the section D2 intersect with each other. This can, for example, facilitate occurrence of a turbulent flow in the two adjacent sections D1 and D2 in the flow direction, compared with when the rear end 121b of the upstream partition 121 and the front end 121a of the downstream partition 121 are in parallel with each other, which leads to further accelerating the mixing of gases.

Moreover, in the present embodiment, the partition 121 in the section D1 is twisted clockwise around the cross-sectional center line CL, and the partition 121 in the section D2 is twisted counterclockwise around the cross-sectional center line CL. Thus, the partition 121 are twisted in different directions in the two sections D1 and D2 adjacent to each other in the flow direction, which makes it easier to generate a turbulent flow compared with, for example, when the partition 121 is twisted in the same direction. Thereby, the mixing of gases can be further accelerated.

Furthermore, in the present embodiment, the connecting passage 14 (introductory passage) extends along the central axis Ax1, and the gas having passed through the connecting passage 14 flows along the central axis Ax1 in one Z direction (downward in FIG. 2). The passage 120 is wound around the connecting passage 14 in a helical manner, and the gas having passed through the passage 120 flows along the central axis Ax1 in the other Z direction (upward in FIG. 2) in a helical manner. The flow straightening passage 13c is opposite to the connecting passage 14 of the passage 120, surrounding the outer periphery of the helical passage 120 and extending along the central axis Ax1. Thus, the gas having passed through the flow straightening passage 13c flows along the central axis Ax1 in one Z direction (downward in FIG. 2). Hence, for example, the connecting passage 14, the helical passage 120, and the flow straightening passage 13c can be efficiently disposed in a relatively small volume, which can make the mixer 10 including the connecting passage 14, the helical passage 120, and the flow straightening passage 13c more compact in size. Moreover, the flow straightening passage 13c is longer in length in the axial direction, therefore, it can further stabilize the turbulent flow caused by swirls in the helical static mixer 12.

Furthermore, in the present embodiment, the mixer 10 includes the helical static mixer 12. According to present embodiment, the static mixer provided in the helical passage 120 can, for example, exert a larger centrifugal force onto the fluids to accelerate the mixing of the fluids than the static mixer provided in a linear passage. Moreover, according to the present embodiment, for example, the static mixer can be made more compact in size.

<Modification>

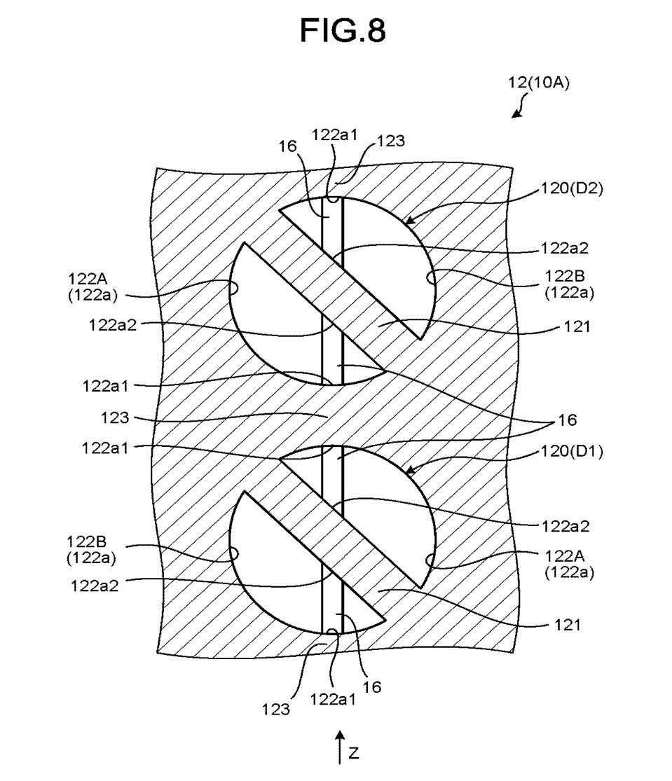

FIG. 8 is a sectional view of a part of a mixer 10A of the present modification. The mixer 10A of the present modification has the same configuration as that of the mixer 10 of the embodiment described above. Thus, the mixer 10A can also attain the functions and results (effects) brought by the same configuration as that of the mixer 10. However, in the present modification, the mixer 10A additionally includes a post 16 in the sections D1 and D2 of the sub-passages 122A and 122B. The post 16 is a bridge connecting a first part 122a1 and a second part 122a2 of an inner surface 122a of the sub-passages 122A and 122B. Of the inner surface 122a, the first part 122a1 is a cylindrical part, and the second part 122a2 is a flat part along the partition 121, facing the first part 122a1. The post 16 may be prismatic or columnar, or may have another sectional shape. The post 16 may also be referred to as a projection. The post 16 is provided so as to partially block the sub-passages 122A and 122B, so that the flow of gas is separated from the surface of the post 16, generating a vortex downstream of the post 16. In other words, the post 16 causes a turbulence in the flow of gas, further accelerating the mixing of gases. The post 16 is an example of a vortex generating element. The vortex generating element is not limited to the post 16, and may be various structures such as a projection and a lattice (grid structure). The vortex generating element may also be referred to as an obstacle, a resistor element, and an agitation accelerator element.

As illustrated in FIG. 8, the post 16 extends in the Z direction, in other words, along the central axis Ax1 and multiple posts 16 are aligned along the central axis Ax1. Thus, the post 16 functions as a support for supporting the partition 121 and a peripheral wall 123 of the passage 120.

### Second Embodiment

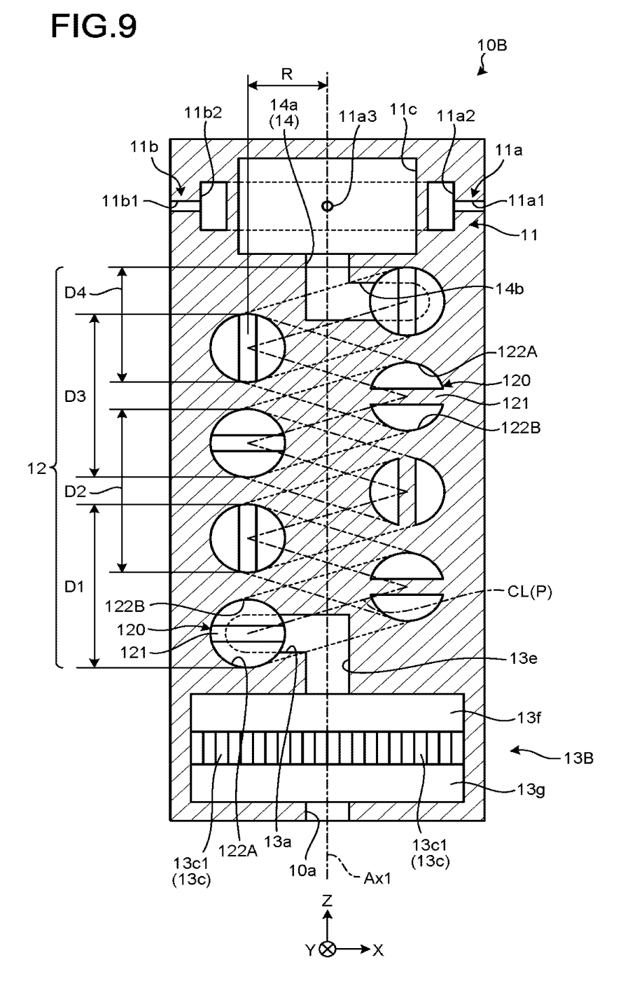

FIG. 9 is a sectional view of a mixer 10B of a second embodiment. As illustrated in FIG. 9, the mixer 10B also has the same configuration as that of the mixer 10 of the first embodiment. Consequently, the mixer 10B can also attain the functions and results (effects) brought by the same configuration as that of the mixer 10. However, the present embodiment differs in the position and configuration of a flow straightening unit 13B. That is, as illustrated in FIG. 9, in the present embodiment, the premixer 11, the helical static mixer 12, and the flow straightening unit 13B are aligned along the central axis Ax1. Such a configuration enables formation of a radially smaller or narrower mixer 10B along the central axis Ax1. In the present embodiment, the configuration of the helical static mixer 12 is the same as that in the first embodiment, however, the upper side of FIG. 9 (premixer 11 side) is upstream of the passage 120, and the lower side of FIG. 9 (flow straightening unit 13B side) is downstream of the passage 120. In other words, the gas reversely flows through the helical static mixer 12 relative to that in the first embodiment, in the order of the section D4, the section D3, the section D2, and the section D1.

The flow straightening unit 13B includes the horizontal hole 13a, a vertical hole 13e, a fifth passage 13f, the flow straightening passage 13c, and a sixth passage 13g. The horizontal hole 13a connects the downstream end of the section D4 in the passage 120 and the vertical hole 13e together. The horizontal hole 13a may be referred to as an introducer of the flow straightening unit 13B. The vertical hole 13e cylindrically extends in the axial direction on the central axis Ax1. The fifth passage 13f is connected to the vertical hole 13e, and has a flat cylindrical shape. The flow straightening passage 13c is continuous with an axial end of the fifth passage 13f (downward in FIG. 2), and includes the parallel holes 13c1 that extends in the axial direction (central axis Ax1) of the cylinder. As in the first embodiment, the cross-section of the holes 13c1 is, for example, in mesh form of densely arranged quadrangles. However, the cross-section thereof is not limited thereto. The sixth passage 13g is continuous with an axial end of the flow straightening passage 13c (downward in FIG. 2) and has a flat cylindrical shape. The gas that has passed through the sixth channel 13g is introduced to the inlet 4a of the lid 4 through the outlet 10a of the mixer 10. The flow of gas is straightened while passing through the fifth passage 13f to the sixth passage 13g of the flow straightening passage 13c.

While certain embodiments have been described, the embodiments have been presented by way of example only, and are not intended to limit the scope of the inventions. Indeed, the novel embodiments described herein may be embodied in a variety of other forms; furthermore, various omissions, substitutions, combinations, and changes in the form of the embodiments described herein may be made without departing from the spirit of the inventions. The accompanying claims and their equivalents are intended to cover such forms or modifications as would fall within the scope and spirit of the inventions. The specifications (including structure, type, direction, shape, size, length, width, thickness, height, angle, number, arrangement, position, and material) of each configuration and form can be suitably modified. For example, the mixer structure and the fluid passage device may be applied to a device other than the semiconductor manufacturing device, or may be used alone. The mixer structure and the fluid passage device can be applied for liquid, plasma, multiphase fluid, gel, gas containing powder, solid with fluidity, and the like, in addition to gas. Substances with fluidity as above are referred to as fluid. The specifications of the passages, the sub-passages, the partition, the helix, and the passage cross-section can be suitably modified. For example, the cross-sectional shape of the passage is not limited to circular. The partition may divide the passage into three or more sub-passages. The twisting amount of the partition, the length of the sections, and the like may be set in various ways. The direction and the number of helixes may also be variously set.

1: A mixer structure provided with a helical passage for fluid, the mixer structure comprising:
a first partition that extends intersecting with a cross-sectional center line of the helical passage, and that divides the helical passage into a plurality of first sub-passages in parallel; and
a second partition that is disposed downstream of the first partition, that extends intersecting with the cross-sectional center line, and that divides the helical passage into a plurality of second sub-passages in parallel, wherein
a rear end of the first partition and a front end of the second partition intersect each other or are at skew position relative to each other, the rear end being a downstream end, the front end being an upstream end.

2: The mixer structure according to claim 1, wherein
the first partition is twisted downstream in one of a clockwise direction and a counterclockwise direction around the cross-sectional center line, and
the second partition is twisted downstream in the other of the clockwise direction and the counterclockwise direction around the cross-sectional center line.

3: The mixer structure according to claim 1, further comprising a vortex generating element in either of the first sub-passages or the second sub-passages.

4: The mixer structure according to claim 3, wherein the vortex generating element extends between a first part and a second part of an inner surface of either of the first sub-passages and the second sub-passages, the second part facing the first part.

5: The mixer structure according to claim 4, wherein the vortex generating element includes vortex generating elements aligned in a third direction and extending in the third direction.

6: A fluid passage device, comprising:
a first mixer including the mixer structure according to claim 1; and
a second mixer that is provided upstream of the first mixer and mixes a plurality of fluids.

7: The fluid passage device according to claim 6, further including a flow straightening unit for straightening a flow, provided downstream of the first mixer.

8: A fluid passage device, comprising:
a first mixer including the mixer structure according to claim 1, and
a flow straightening unit for straightening a flow, provided downstream of the first mixer.

9: The fluid passage device according to claim 7, wherein the flow straightening unit is more radially outside than the helical passage and extends along a central axis of a helix of the helical passage.

10: A fluid passage device, comprising:
a first mixer having the mixer structure according to claim 1, wherein
an introductory passage for fluid to the first mixer extends along a central axis of a helix of the helical passage, and
the helical passage is wound around the introductory passage.

11: A processing device, comprising:
the fluid passage device according to claim 6, and
a processing unit that supports an intended object and that supplies fluid to the object through the fluid passage device.
